(19) United States
(12) Patent Application Publication
(10) Pub. No.: US 2016/0295757 A1
(43) Pub. Date: Oct. 6, 2016

(54) COMPONENT MOUNTING LINE, COMPONENT MOUNTING METHOD AND COMPONENT MOUNTING APPARATUS

(71) Applicant: Panasonic Intellectual Property Management Co., Ltd., Osaka (JP)

(72) Inventors: Katsuhiko ITOH, Yamanashi (JP); Masanori IKEDA, Yamanashi (JP); Kenji OKAMOTO, Hyogo (JP)

(21) Appl. No.: 14/993,852

(22) Filed: Jan. 12, 2016

(30) Foreign Application Priority Data
Mar. 31, 2015 (JP) 2015-070520

(51) Int. Cl. H05K 13/08; H05K 3/34; H05K 13/04

(52) U.S. Cl. CPC H05K 13/08; H05K 13/0465; H05K 3/3452; H05K 3/341

(57) ABSTRACT

A component mounting line includes an inspecting apparatus and a component mounting apparatus. The inspecting apparatus measures a solder volume of a printed solder on each electrode of a board. The component mounting apparatus includes a mounting unit that mounts an electronic component on the board, at least one component supply unit that supplies a chip solder, and a control unit that controls the mounting unit to mount the chip solder supplied from the component supply unit based on production data in which a size of the chip solder is instructed corresponding to the solder volume measured for each of component terminals corresponding to each electrode of the board.

### CROSS-REFERENCES TO RELATED APPLICATION(S)

This application is based on and claims priority from Japanese Patent Application No. 2015-70520 filed on Mar. 31, 2015, the entire contents of which are incorporated herein by reference.

### BACKGROUND

1. Field of the Invention

The present invention relates to a component mounting line, a component mounting method and a component mounting apparatus for mounting a component on a board.

2. Description of Related Art

In the manufacture of a mounting board on which an electronic component (hereinafter referred to as a “component”) is mounted, a printer transfers cream solder on an electrode (hereinafter, referred to as a “land”) for bonding the component of the board through a metal mask, a component mounting apparatus mounts the component on the board, and then, the cream solder is melted through reflow such that a component terminal is bonded to the land. In recent years, an opening area of the metal mask has become smaller according to miniaturization of the component and pitches between the component terminals have become narrower, and therefore a thin metal mask is used in order to cope with a printing defect due to deterioration in spreading the solder.

Meanwhile, depending on the transferring state of cream solder, only in a case of cream solder supplied to a land through a metal mask, there is a case where the solder amount is partially insufficient. Thus, there has been proposed a method in which a chip-shaped solder (hereinafter referred to as “chip solder”) is mounted on a land in which the solder amount is insufficient to supplement the insufficient solder amount (for example, refer to JP-A-6-275944 as Patent Document 1). In a method disclosed in JP-A-6-275944, a plurality of types of chip solder having the same size as a component are prepared, and any one type of chip solder is mounted on a board at the same time when the component is mounted.

Patent Document 1: JP-A-6-275944

### SUMMARY

However, in technologies of the related art including JP-A-6-275944, when chip solder is mounted on a board in a component mounting apparatus, a specific method of designating an appropriate size of chip solder to be mounted is not disclosed. Thus, there is a problem in that it is difficult to designate and to mount pieces of appropriately sized chip solder on a vast multitude of lands on a board.

A non-limited object of one or more aspects of the present invention is to provide a component mounting line, a component mounting method and a component mounting apparatus, in which it is possible to mount appropriately sized chip solder on a board.

A component mounting line according to an aspect of the present invention includes: an inspecting apparatus; and a component mounting apparatus, wherein the inspecting apparatus measures a solder volume of a printed solder on each electrode of a board, and wherein the component mounting apparatus includes a mounting unit that mounts an electronic component on the board, at least one component supply unit that supplies a chip solder, and a control unit that controls the mounting unit to mount the chip solder supplied from the component supply unit based on production data in which a size of the chip solder is instructed corresponding to the solder volume measured for each of component terminals corresponding to each electrode of the board.

A component mounting method according to an aspect of the present invention includes: measuring a solder volume of solder printed on each electrode of a board; mounting chip solder supplied based on production data in which a size of the chip solder is instructed corresponding to the measured solder volume for each of component terminals corresponding to each electrode of the board; and mounting an electronic component on the board.

A component mounting apparatus according to an aspect of the present invention includes: an inspecting unit that measures a solder volume of solder printed on each electrode of a board; a mounting unit that mounts an electronic component on the board; at least one component supply unit that supplies chip solder; and a control unit that controls the mounting unit to mount the chip solder supplied from the component supply unit based on production data in which a size of the chip solder is instructed corresponding to the solder volume measured for each of component terminals corresponding to each electrode of the board.

According to the aspects of the present invention, it may be possible to mount chip solder having an appropriate size on a board.

### BRIEF DESCRIPTION OF THE DRAWINGS

FIG. 1 is a block diagram illustrating the configuration of a component mounting line according to an embodiment of the present invention.

FIG. 2 is a plan view illustrating the configuration of a component mounting apparatus according to the embodiment of the present invention.

FIG. 3 is a perspective diagram illustrating the component and the chip solder mounted on the board by the component mounting line according to the embodiment of the present invention.

FIG. 4 is a block diagram illustrating the configuration of a control system of the component mounting line according to the embodiment of the present invention.

FIG. 5 is a table illustrating the configuration of component data based on the ideal amount of the solders used in the component mounting line according to the embodiment of the present invention.

FIG. 6 is a table illustrating the configuration of component data based on the theoretical amount of the solders used in the component mounting line according to the embodiment of the present invention.

FIG. 7 is a diagram illustrating an example of the component mounted on the board by the component mounting line according to the embodiment of the present invention.

FIG. 8 is a table illustrating a configuration of mounting position data used in the component mounting line according to the embodiment of the present invention.

FIG. 9 is a diagram illustrating an example of a board on which the component is mounted by the component mounting line according to the embodiment of the present invention.

FIG. 10 is a table illustrating the configuration of inspection result information created in the component mounting line according to the embodiment of the present invention.

FIG. 11 is a diagram illustrating an example of a board on which the component is to be mounted by the component mounting line according to the embodiment of the present invention.

FIG. 12 is a flowchart illustrating component mounting operation by the component mounting line according to the embodiment of the present invention.

FIG. 13 is a table illustrating an example of production data generated in the component mounting line according to the embodiment of the present invention.

FIG. 14 is a diagram illustrating an example of a board on which the component and the chip solder are mounted by the component mounting line according to the embodiment of the present invention.

FIG. 15 is a block diagram illustrating the configuration of a component mounting line according to a second example of the embodiment of the present invention.

FIG. 16 is a plan diagram illustrating a configuration of an inspection and mounting apparatus according to the second example of the embodiment of the present invention.

FIG. 17 is a block diagram illustrating the configuration of a control system of the component mounting line according to the second example of the embodiment of the present invention.

### DETAILED DESCRIPTION

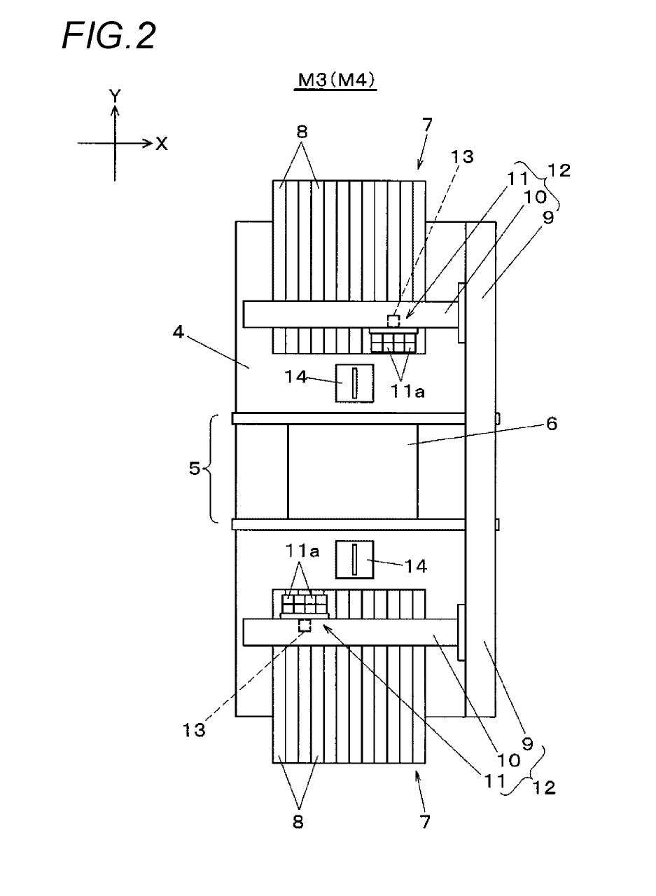

Next, embodiments of the present invention herein will be described with reference to the accompanying drawings. Hereinafter, a board transport direction (the horizontal direction on the paper surface in FIG. 2) is defined as an X direction, and a direction (the vertical direction on the paper surface in FIG. 2) orthogonally intersecting with the X direction in a horizontal plane is defined as a Y direction.

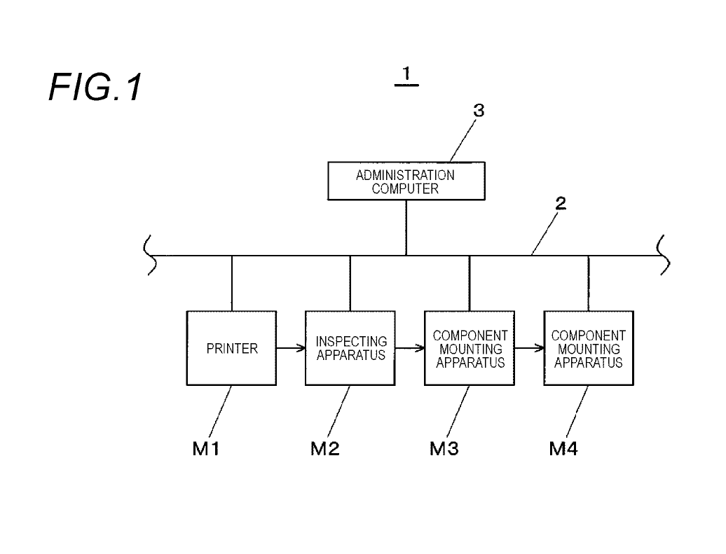

First, a component mounting line 1 will be described with reference to FIG. 1. The component mounting line 1 in FIG. 1 is configured to connect respective apparatuses of a printer M1, an inspecting apparatus M2, and component mounting apparatuses M3 and M4 that are a plurality of component mounting apparatuses, to connect each apparatus with a communication network 2, and to control the entirety of the apparatuses with an administration computer 3.

The printer M1 has a function of transferring a paste-like cream solder through a metal mask on a land formed on the board by using screen printing. The inspecting apparatus M2 has a function of inspecting the state of the transfer (printing) of the cream solder by measuring the solder volume (solder amount) or the solder volume rate of the cream solder printed on each land (electrode) of the board. The component mounting apparatuses M3 and M4 have a function of picking up a component from a component supply unit by a mounting head and transporting and mounting the component at a mounting position of the board on which the cream solder is transferred.

In this manner, the component mounting line 1 includes the inspecting apparatus M2 and the component mounting apparatuses M3 and M4, and mounts the component (electronic component) on the board on which the cream solder is printed. The board is subjected to a reflow process after the component is mounted thereto, and the mounting board is manufactured by melting the cream solder and bonding the component terminal of the component mounted on the board with the land of the board by solder.

Next, the component mounting apparatuses M3 and M4 will be described with reference to FIG. 2. Since the component mounting apparatuses M3 and M4 have the same structure, only the component mounting apparatus M3 will be mentioned here. In FIG. 2, at the center part of a base 4, a board transport unit 5 is arranged along the X direction. The board transport unit 5 has functions of transporting a board 6 which is a target of mounting operation of a component carried from an upstream side, and of holding and positioning the component at the mounting operation position where component mounting operation is performed by a mounting unit to be described hereinafter.

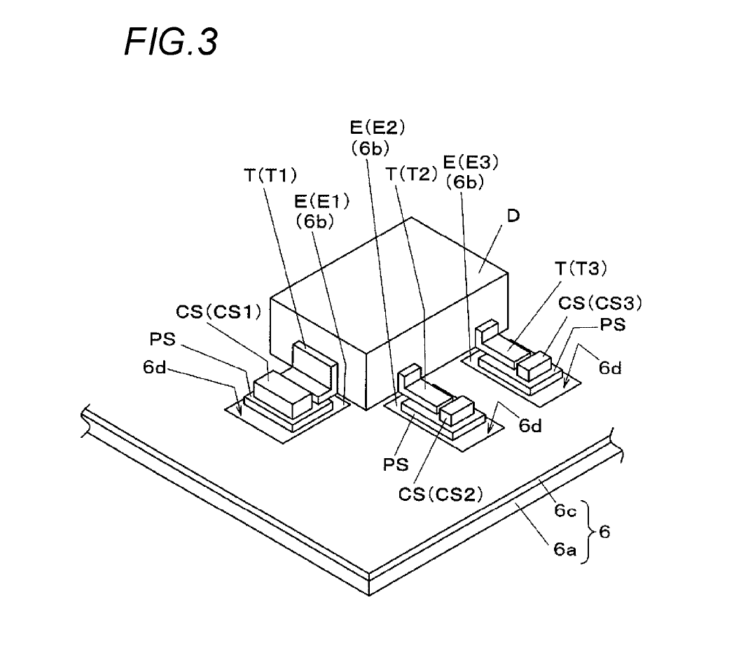

At the both outer sides along the Y direction of the board transport unit 5, component supply units 7 that supply a component which is a target of mounting operation are arranged. In the component supply unit 7, a plurality of tape feeders 8 are arranged in parallel. The tape feeders 8 have a function of pitch-feeding a component D or chip solder CS (refer to FIG. 3) held in a carrier tape to a fetching position by the mounting unit. That is, the component mounting apparatuses M3 and M4 include a plurality of the tape feeders 8 each of which is means for supplying a component, are capable of supplying chip solders CS in different sizes, and further includes a different tape feeder 8 that supplies the component D (electronic component).

At the end portion of one side of the X direction of the upper surface of the base 4, a Y-axis moving table 9 is arranged. To the Y-axis moving table 9, two of X-axis moving tables 10 are slidably joined in the Y direction. To the X-axis moving table 10, each of mounting heads 11 is slidably mounted in the X direction. The Y-axis moving table 9 and the X-axis moving table 10 configure a head traveling mechanism that moves the mounting heads 11 in a horizontal surface. Driving of the head traveling mechanism allows the mounting heads 11 to travel between the component supply unit 7 and the board 6 positioned and held at the mounting operation position by the board transport unit 5.

The mounting head 11 is a multi-type head formed of a plurality of unit holding heads 11a. A suction nozzle is mounted on the lower end portion of the unit holding head 11 a so that the component D or the chip solder CS sent to the fetching position of the tape feeder 8 is subjected to vacuum suction and held, and is mounted at a predetermined mounting position on the board 6 positioned and held at the mounting operation position. In this manner, the head traveling mechanism and the mounting head 11 configure a mounting unit 12 that mounts the component D (electronic component) or the chip solder CS on the board 6.

On the under surface of each of the X-axis moving table 10, board recognition cameras 13 that travel integrally with each of the mounting heads 11 are mounted. The driving of the head traveling mechanism allows the board recognition cameras 13 to travel above the board 6 positioned and held by the board transport unit 5 and thereby, the board recognition cameras 13 image the board 6 from above. A component recognition camera 14 is arranged between the component supply unit 7 and the board transport unit 5. The mounting head 11 that has fetched the component D or the chip solder CS from the component supply unit 7 performs a scanning operation of passing above the component recognition camera 14 in a predetermined direction and thereby, the component recognition camera 14 images the component D or the chip solder CS which is in a state of being held by the mounting head 11.

Next, the board 6, and the component D and the chip solder CS which are mounted on the board 6 by the component mounting line 1 will be described with reference to FIG. 3. The board 6 in FIG. 3 has a structure in which a wiring layer 6b (circuit pattern) formed on the surface of an insulation board 6a which is a base is covered with a solder resist 6c having insulation properties. In the solder resist 6c, a solder resist opening 6d is formed at a position at which the circuit pattern formed on the board 6 is bonded to a component terminal T of the component D, and an electrode (land E) through which the wiring layer 6b is exposed on the surface of the board 6 is formed.

In FIG. 3, cream solder PS is transferred by the printer M1 above each of lands E (E1 to E3). The component D is mounted at a predetermined mounting position by the component mounting apparatuses M3 and M4 such that each of component terminals T (T1 to T3) come into contact with the predetermined lands E (E1 to E3) through the cream solder PS. Pieces of chip solders CS (CS1 to CS3) are mounted on each of the lands E (E1 to E3), which supplement the amount of insufficient solders when the transferred cream solder PS alone is not sufficient. In an example in FIG. 3, the large piece of chip solder CS1 is mounted on the land E1, the small pieces of chip solders CS2 and CS3 and the pieces of chip solders CS with different sizes are mounted on the lands E2 and E3.

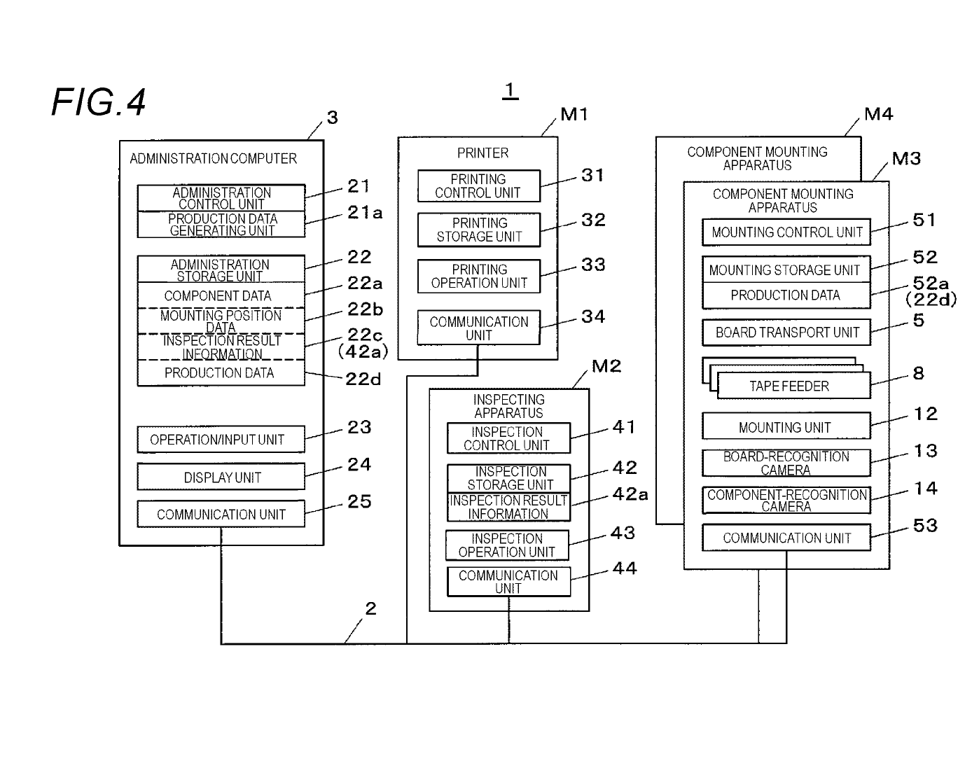

Next, the configuration of the control system of the component mounting line 1 will be described with reference to FIG. 4. In FIG. 4, the administration computer 3 includes an administration control unit 21, an administration storage unit 22, operation/input unit 23, and a display unit 24, and is connected to the communication network 2 through a communication unit 25. The administration control unit 21 has a function of performing overall control in each of the apparatuses which configure the component mounting line 1. Further, the administration control unit 21 includes a production data generating unit 21a. The production data generating unit 21a computes various types of data stored in the administration storage unit 22 to be described hereinafter, and performs a production data generating operation of generating production data which is referred to in the mounting operation of the component D and the chip solder CS in the component mounting apparatuses M3 and M4.

The administration storage unit 22 stores component data 22a, mounting position data 22b, inspection result information 22c, production data 22d, and the like, in addition to production administration data with which an operation to be performed by the component mounting line 1 is administrated. The component data 22a is data of a shape or the like of the component D which is mounted on the board 6. The mounting position data 22b is data of a type of the component D which is mounted on the board 6, and an X or Y coordinate or the like of a mounting position.

The inspection result information 22c is data that includes the solder volume (measured solder amount VM) of the cream solder PS printed on each of the lands E of the board 6 measured by an inspecting apparatus M2 to be described hereinafter, which is stored in the administration storage unit 22 by being received through the communication network 2 and the communication unit 25. The production data 22d is data which is generated by the production data generating unit 21a and is referred to in the mounting operation in the component mounting apparatuses M3 and M4. The production data 22d is transmitted to the component mounting apparatuses M3 and M4 through the communication unit 25 and the communication network 2, and is stored in mounting storage units 52 of the component mounting apparatuses M3 and M4. The various types of data will be described below in detail.

The operation/input unit 23 is an input device such as a keyboard or a touch panel provided on a display screen of the display unit 24, and performs an operation to instruct regarding an operation or to input data. The display unit 24 is a display device such as a liquid crystal panel and displays an input screen or the like of the various types of data.

The printer M1 in FIG. 4 includes a printing control unit 31, a printing storage unit 32, and a printing operation unit 33, and is connected to the communication network 2 through a communication unit 34. The printing control unit 31 controls the printing operation unit 33 based on various types of programs or data stored in the printing storage unit 32 and thereby, screen printing of the cream solder PS is performed on the board 6 through the metal mask.

In FIG. 4, the inspecting apparatus M2 includes an inspection control unit 41, an inspection storage unit 42, and an inspection operation unit 43, and is connected to the communication network 2 through a communication unit 44. The inspection operation unit 43 includes a three-dimensional sensor including a laser light scanning type sensor or the like. The inspection control unit 41 controls the inspection operation unit 43 based on various types of programs or data stored in the inspection storage unit 42 and thereby, the shape of the cream solder PS printed on each of the lands E of the board 6 is measured in a three-dimensional manner.

The inspection control unit 41 computes the measured solder amount VM that is the solder volume of the cream solder PS of each of the lands E by arithmetically processing the measurement result. The computed measured solder amount VM is stored in the inspection storage unit 42 as inspection result information 42a. The inspection result information 42a is transmitted to the administration computer 3 through the communication unit 44 and the communication network 2, and is stored in the administration storage unit 22 as the inspection result information 22c.

Each of the component mounting apparatuses M3 and M4 in FIG. 4 includes a mounting control unit 51, a mounting storage unit 52, the board transport unit 5, the plurality of tape feeders 8, the mounting unit 12, the board recognition camera 13, and the component recognition camera 14, and is connected to the communication network 2 through a communication unit 53. The mounting control unit 51 is a computing device, and controls each unit to be described hereinafter based on various types of programs or data stored in the mounting storage unit 52. The mounting storage unit 52 stores the production data 22d transmitted from the administration computer 3 as production data 52a. The production data 52a is data which is used to mount the component D and the chip solder CS on the board 6.

The board transport unit 5 is controlled by the mounting control unit 51, transports the board 6, and positions and holds the board 6 at the mounting operation position. The tape feeder 8 is controlled by the mounting control unit 51 and supplies the component D or the chip solder CS to the fetching position. The mounting unit 12 is controlled by the mounting control unit 51 and carries and mounts the component D or the chip solder CS supplied to the fetching position to the predetermined mounting position of the positioned and held board 6. In addition, the mounting control unit 51 performs a recognition processing of an imaging result by the board recognition camera 13 and the component recognition camera 14, and performs correction of the mounting position of the component D or the chip solder CS based on the recognition result.

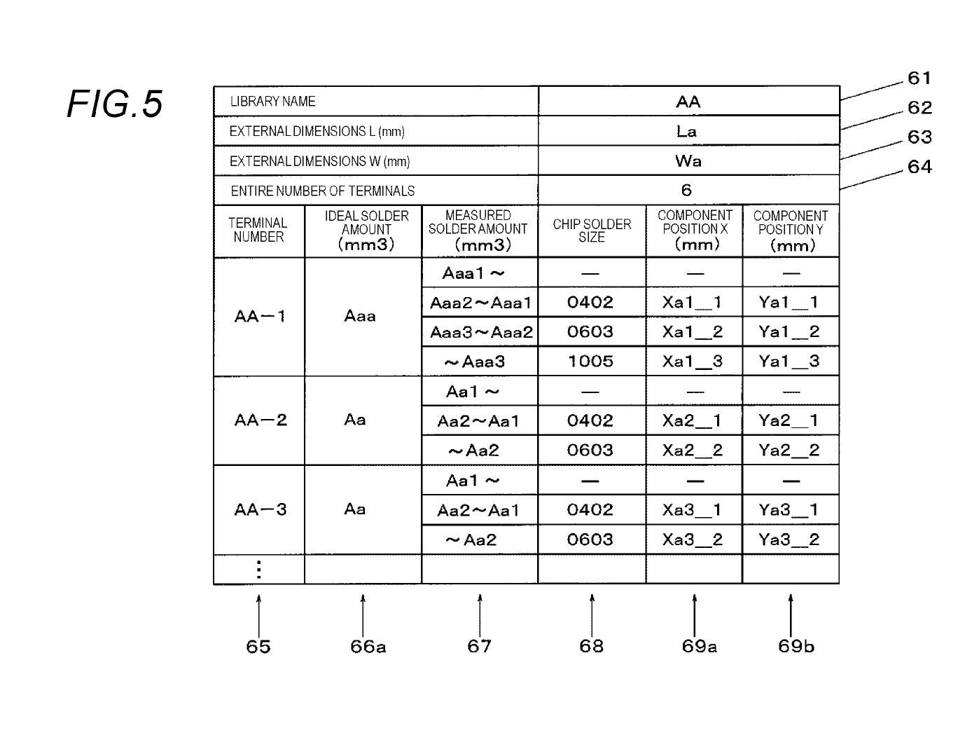

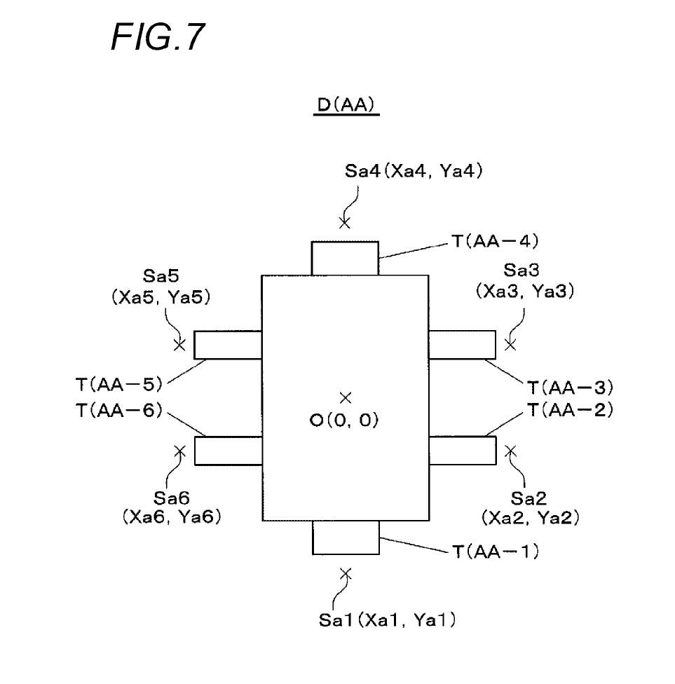

Next, details of various data stored in each storing unit of the component mounting line 1 will be described with reference to FIGS. 5 to 11. First, the component data 22a will be described with reference to FIGS. 5 to 7. FIG. 5 illustrates the configuration of the component data 22a based on an ideal solder amount VI of the component D (AA) illustrated in FIG. 7. In FIG. 5, terminal numbers (AA-1 to AA-6) are assigned to each of the component terminals T of the component D (AA). In FIG. 5, among the six component terminals T, only three terminal numbers (AA-1 to AA-3) are displayed, and the display of the remaining terminal numbers (AA-4 to AA-6) is omitted.

In the component data 22a, the type (AA) of the component D is recorded in a “library name” column 61, external dimensions L (La) of the component D are recorded in an “external dimensions L” column 62, external dimensions W (Wa) of the component D are recorded in an “external dimensions W” column 63, and the number (6) of the component terminals T is recorded in an “entire terminal number” column 64.

In addition, in the component data 22a, corresponding to the terminal numbers (AA-1 to AA-6) of a “terminal number” column 65, in a case where the land E bonded to the component terminal T has a standard shape which is recommended in a data sheet or the like, the ideal solder amount VI (Aaa and Aa) is designated in an “ideal solder amount” column 66a. The ideal solder amount VI is the ideal solder amount required for solder bonding of the component terminal T to the land E (electrode) of the board 6. In this example, the same ideal solder amount VI is designated to the component terminals T having the same shape.

In addition, in the component data 22a in FIG. 5, corresponding to the classification of the extent of the measured solder amount VM of a “measured solder amount” column 67, the size (type) of the chip solder CS to be mounted on the land E in a “chip solder size” column 68 is designated. The size of the chip solder CS corresponding to the scope of the classification (sorting) of the measured solder amount VM is designated as a size in a scope appropriate for supplementing the measured solder amount VM of the insufficient solder amount based on the ideal solder amount VI of each of the component terminals T. The scope of the measured solder amount VM in this example is made such that the terminal number (AA-1) is classified into four classifications and the terminal numbers (AA-2 and AA-3) are classified into three classifications.

In the component terminal T of the terminal number (AA-1), in order of smallest to largest, a chip solder CS of the size 1005 is designated to the classification of the measured solder amount VM less than Aaa3, a chip solder CS of the size 0603 is designated to the classification of the measured solder amount VM equal to or more than Aaa3 and less than Aaa2, and a chip solder CS of the size 0402 is designated to the classification of the measured solder amount VM equal to or more than Aaa2 and less than Aaa1. The classification of the measured solder amount VM equal to or more than Aaa1 corresponds to an empty column (displayed as [—] in the drawing) not being designated with the chip solder CS, and therefore in this classification, the chip solder CS is not mounted. In the same manner, in the component terminals T of the terminal numbers (AA-2 and AA-3), a chip solder CS of the size 0603 is designated to the classification of the measured solder amount

VM less than Aa2, and a chip solder CS of the size 0402 is designated to the classification of the measured solder amount VM equal to or more than Aa2 and less than Aa1, and the classification of the measured solder amount VM equal to or more than Aa1 corresponds to a blank column.

Further, in the component data 22a, for each of the component terminals T, with mounting positions S (Sa1 to Sa6) at which the chip solder CS is mounted as coordinates relatively displayed from the center O of the component D (AA), X coordinates (Xa1_1 to Xa1_3, Xa2_1 and Xa2_2, and Xa3_1 and Xa3_2) are designated to a “component position X” column 69a, and Y coordinates (Ya1_1 to Ya1_3, Ya2_1 and Ya2_2, and Ya3_1 and Ya3_2) are designated to a “component position Y” column 69b. At the mounting positions S (Sa1 to Sa6), the X coordinates and the Y coordinates are designated corresponding to the size of the chip solder CS for each of the component terminals T. Thereby, a defect in which the component terminal T is interfered in the case where the mounted chip solder CS is large, or the chip solder CS is mounted while falling off from the land E in the case where the mounted chip solder CS is small, can be prevented.

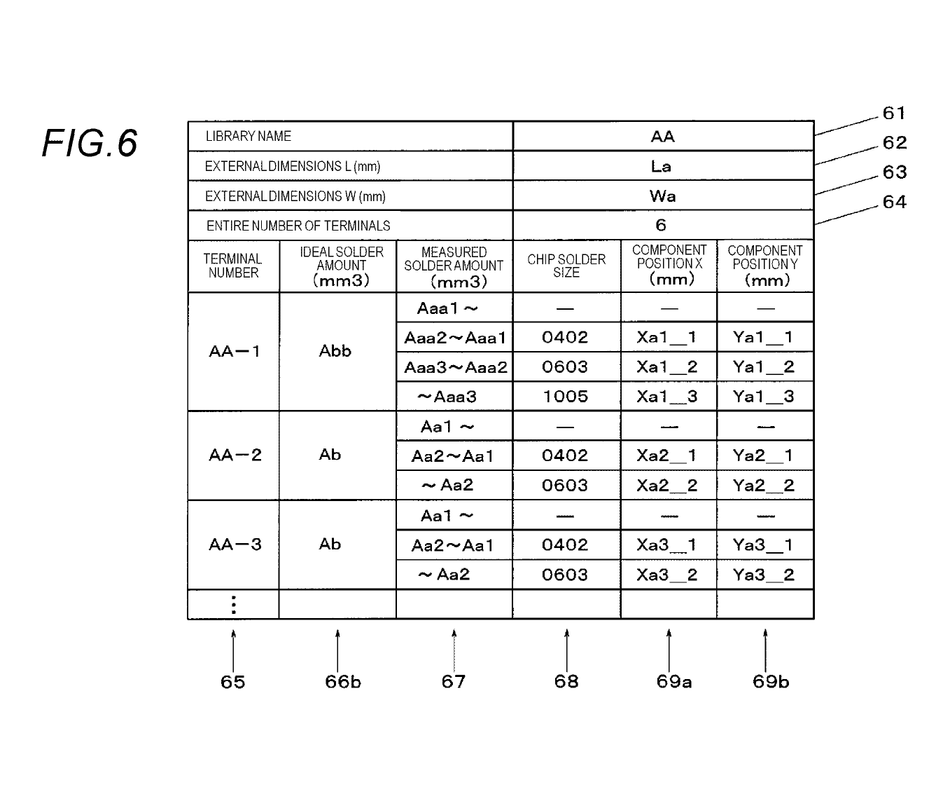

FIG. 6 illustrates the configuration of the component data 22a based on a theoretical solder amount VT of the component D (AA) illustrated in FIG. 7. The component data 22a based on the theoretical solder amount VT is the same with the component data 22a based on the ideal solder amount VI except for that the “ideal solder amount” column 66a is replaced with a “theoretical solder amount” column 66b. Therefore, the description of the same columns will be omitted hereinafter. In the “theoretical solder amount” column 66b, the opening size of the mask used for printing the cream solder PS on the board 6 in the printer M1 and the theoretical solder amount VT (Abb and Ab) found from the mask thickness are designated. The theoretical solder amount VT is the volume of the solder transferred on each of the lands E of the board 6 in a case where the opening of the mask is ideally filled with the cream solder PS.

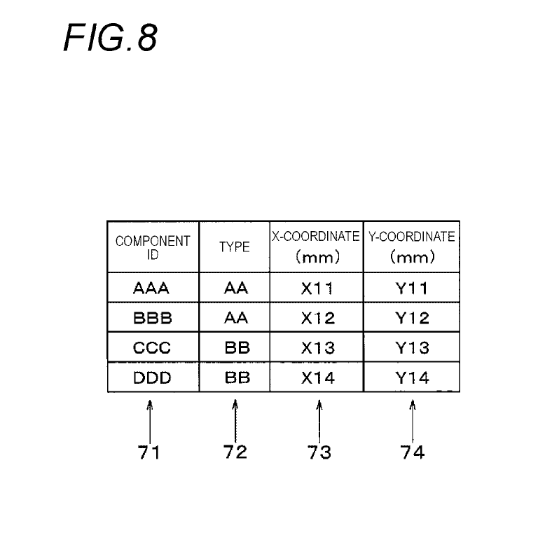

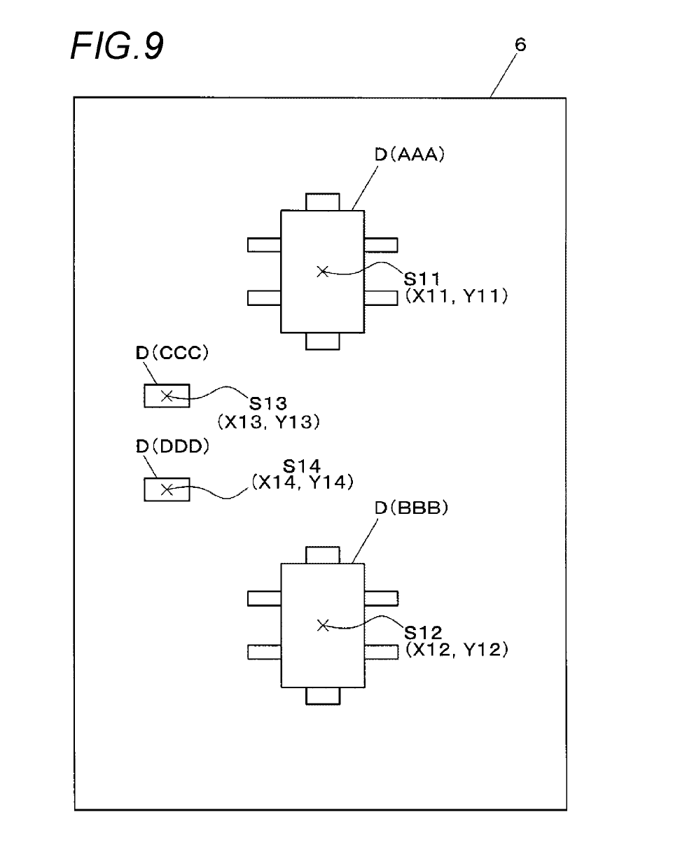

Next, the mounting position data 22b will be described with reference to FIGS. 8 and 9. FIG. 8 illustrates the configuration of the mounting position data 22b of the board 6 on which four components D illustrated in FIG. 9 are mounted. Component numbers (AAA, BBB, CCC, and DDD) are attached to each of the components D. In the mounting position data 22b, corresponding to the component numbers (AAA, BBB, CCC, and DDD) of a “component ID” column 71, types (AA, BB, CC, and DD) of the component D are recorded in a “type” column 72, and X coordinates (X11 to X14) and Y coordinates (Y11 to Y14) of mounting positions S (S11 to S14) of the component D on the board 6 are recorded in an “X coordinate” column 73 and a “Y coordinate” column 74. In addition, the types of the component D of the “type” column 72 are associated with the types of the component D in the “library name” column 61 of the component data 22a illustrated in FIGS. 5 and 6.

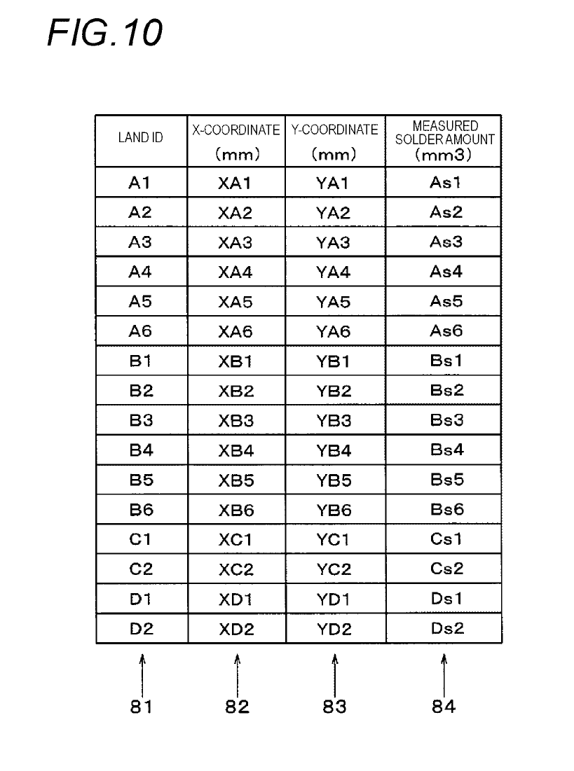

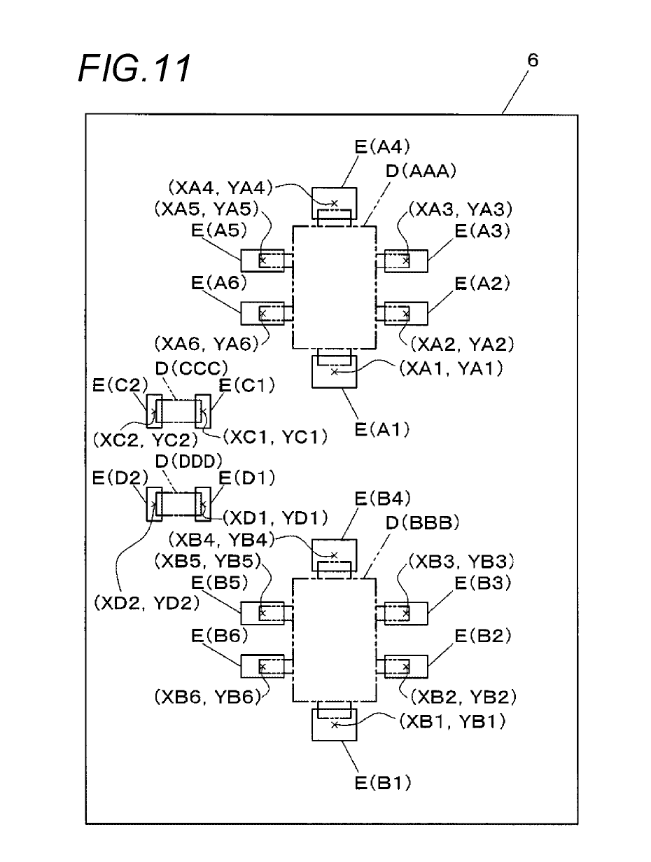

Next, the inspection result information 22c (inspection result information 42a) will be described with reference to FIGS. 10 and 11. FIG. 10 illustrates the configuration of the inspection result information 22c of the cream solder PS printed on the land E of the board 6 (refer to FIG. 9) on which four components D illustrated in FIG. 11 are mounted. In FIG. 11, on the board 6, the lands E bonded to each of the component terminals T of the four mounted components D (AAA, BBB, CCC, and DDD) are formed. The land IDs (A1 to A6, B1 to B6, C1 and C2, and D1 and D2) are attached to each of the lands E.

In the inspection result information 22c, corresponding to the land IDs (A1 to A6, B1 to B6, C1 and C2, and D1 and D2) of a “land ID” column 81, X coordinates (XA1 to XA6, XB1 to XB6, XC1 and XC2, and XD1 and XD2) and Y coordinates (YA1 to YA6, YB1 to YB6, YC1 and YC2, and YD1 and YD2) of the land E are stored in an “X coordinate” column 82 and a “Y coordinate” column 83. In addition, in a “measured solder amount” column 84, measured solder amount VM (As1 to As6, Bs1 to Bs6, Cs1 and Cs2, and Ds1 and Ds2) of each of the lands E measured by the inspecting apparatus M2 are stored.

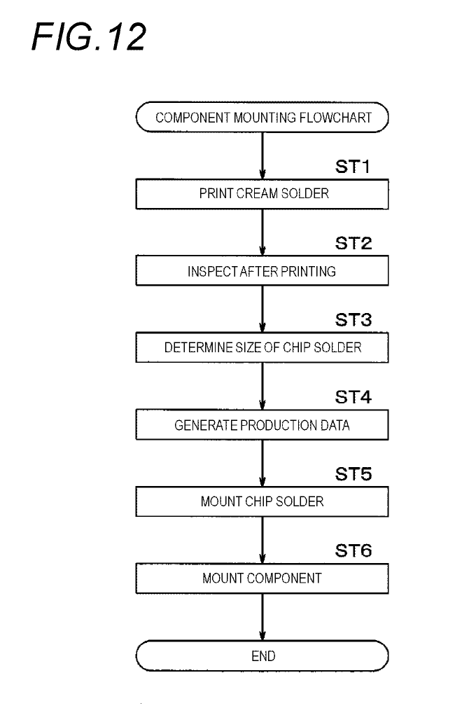

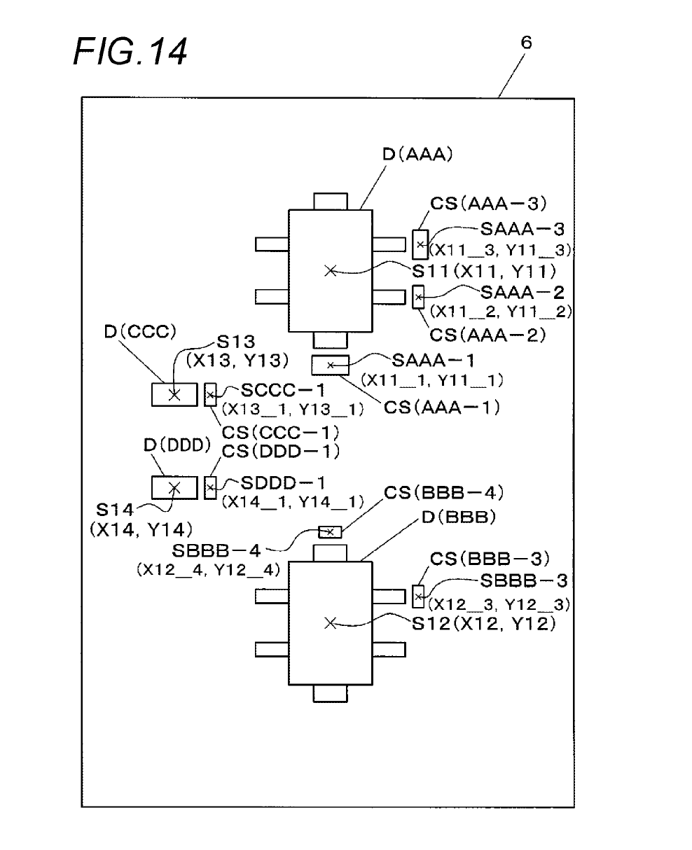

Next, the component mounting operation (component mounting method) by the component mounting line 1 of the present embodiment and production data 22d generated in the component mounting operation will be described with reference to a flowchart in FIG. 12 and FIGS. 13 and 14. In FIG. 12, the printer M1 prints the cream solder PS on each of the lands E of the board 6 (ST1: printing process). Next, the inspecting apparatus M2 measures the measured solder amount VM (solder volume) of the cream solder PS printed on each of the lands E (electrode) of the board 6 (ST2: inspecting process). The measured solder amount VM is stored in the inspection storage unit 42 as the inspection result information 42a, and is also transmitted to the administration computer 3 and stored in the administration storage unit 22 as inspection result information 22c.

Next, the production data generating unit 21a of the administration computer 3 determines the size of the chip solder CS to be additionally mounted on each of the lands E of the board 6 based on the component data 22a, the mounting position data 22b, and the inspection result information 22c stored in the administration storage unit 22 (ST3: size determining process). Specifically, according to the measured solder amount VM of the inspection result information 22c it is determined that the size of the chip solder CS coinciding with the classification corresponding to the component data 22a is the size of the chip solder CS to be mounted. In addition, in the land E where the solder amount of the cream solder PS required for bonding the component terminal T is printed, the chip solder CS is not mounted.

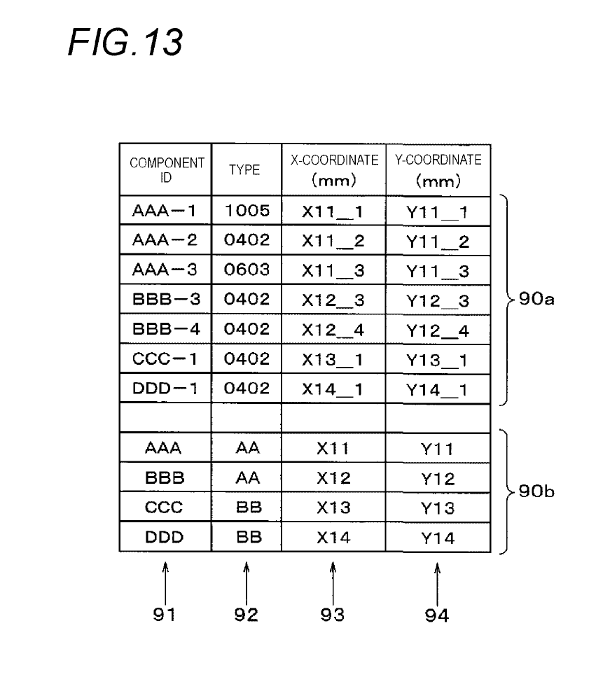

Next, the production data generating unit 21a generates production data 22d based on the size of the chip solder CS determined in the size determining process (ST3) and the mounting position data 22b (ST4: production data generating process). The generated production data 22d is stored in the administration storage unit 22, and is also transmitted to the component mounting apparatuses M3 and M4, and is stored in the mounting storage unit 52 as production data 52a. Here, with reference to FIG. 13, an example of the generated production data 22d will be described. In the production data 22d, the type of the chip solder CS mounted on the board 6 in the component mounting apparatuses M3 and M4 and the type of component D, and the data of the X- and Y-coordinates of the mounting position S are included. In FIG. 13, a first portion 90a is the data related to the chip solder CS, and a latter part 90b is the data related to the component D.

In FIG. 13, chip solder numbers (AAA-1 to AAA-3, BBB-3 and BBB-4, CCC-1, and DDD-1) and the component numbers (AAA, BBB, CCC, and DDD) are recorded in a “component ID” column 91. In addition, corresponding to the chip solder numbers or the component numbers, the type of the chip solder CS or the component D is recorded in a “type” column 92. In an “X coordinates” column 93 and a “Y coordinates” 94, X coordinates (X11_1 to X11_3, X12_3 and X12_4, X13_1, X14_1, and X11 to X14) and Y coordinates (Y11_1 to Y11_3, Y12_3 and Y12_4, Y13_1, Y14_1, and Y11 to Y14) of the mounting positions S (SAAA-1 to SAAA-3, SBBB-3 and SBBB-4, SCCC-1, SDDD-1, and S11 to S14) of the chip solder CS on the board 6 and the component D are recorded.

In addition, even in the case of the component D of the same type mounted on the same board 6, there is a case where the addition of solder by the chip solder CS is not preferable at the point where the space between the component terminals T becomes closer due to the components D being concentrated, or the like. In this case, it is possible to suppress (in the production data 22d, the corresponding point does not designate the chip solder CS) the mounting of the chip solder CS by the following method. For example, when the mountability information of the chip solder CS for each of the component IDs in the mounting position data 22b is added, and thereby the production data 22d is generated, it may be designated that the chip solder CS is not mounted on the component D on which the chip solder CS is “not mountable”.

In addition, when separately preparing a “non-mountability designation file” that designates a component D or a land E on which the chip solder CS is not mounted, and thereby the production data 22d is generated, the production data 22d may be generated also with reference to the “non-mountability designation file”. Moreover, in the component D of the same type, the component data 22a in which the entire “chip solder size” columns 68 are made to be a blank column (when the chip solder CS is not mounted) may be prepared, and the corresponding component data 22a may be designated by the component D on which the chip solder CS is not mounted in the mounting position data 22b.

In FIG. 12, the component mounting apparatuses M3 and M4 mount the chip solder CS supplied from the tape feeder 8 by the mounting unit 12 based on the production data 52a stored in the mounting storage unit 52 on the predetermined land E of the board 6 (ST5: chip solder mounting process). That is, the mounting control unit 51 (control unit) in the chip solder mounting process (ST5) controls so that the mounting unit 12 mounts the chip solder CS supplied from the tape feeder 8 (component supply means) based on the production data 52a in which the size of the chip solder CS is instructed corresponding to the measured solder amount VM (solder volume) measured for each of the component terminals T corresponding to each of the lands E (electrode).

Next, the component mounting apparatuses M3 and M4 mount the component D (electronic component) supplied from the tape feeder 8 by the mounting unit 12 to the predetermined position of the board 6 based on the production data 52a stored in the mounting storage unit 52 (ST6: component mounting process). The component mounting line 1 repeats the flow above, and thereby the measured solder amount VM for each of the board 6 on which the cream solder PS is printed is measured, the production data 52a based on the measured solder amount VM is generated, and the chip solder CS and the component D is mounted on the board 6.

As described above, in the component mounting line 1 and the component mounting method according to the present embodiment, the measured solder amount VM (solder volume) of the solder printed on each of the lands E (electrode) of the board 6 is measured in the inspecting apparatus M2, and the production data 52a in which the size of the chip solder CS that supplements the insufficient solder amount for each of the lands E based on the measured solder amount VM is instructed, is generated. In addition, in the component mounting line 1 and the component mounting method, the chip solder CS supplied from the tape feeder 8 (component supply means) is mounted by the mounting unit 12 in the component mounting apparatuses M3 and M4 based on the production data 52a. Thereby, in a case where the solder amount of the cream solder PS printed on the land E of the board 6 is insufficient compared to the solder amount required for forming preferable bonding, it is possible to additionally mount the appropriately sized chip solder CS to supplement the insufficient amount.

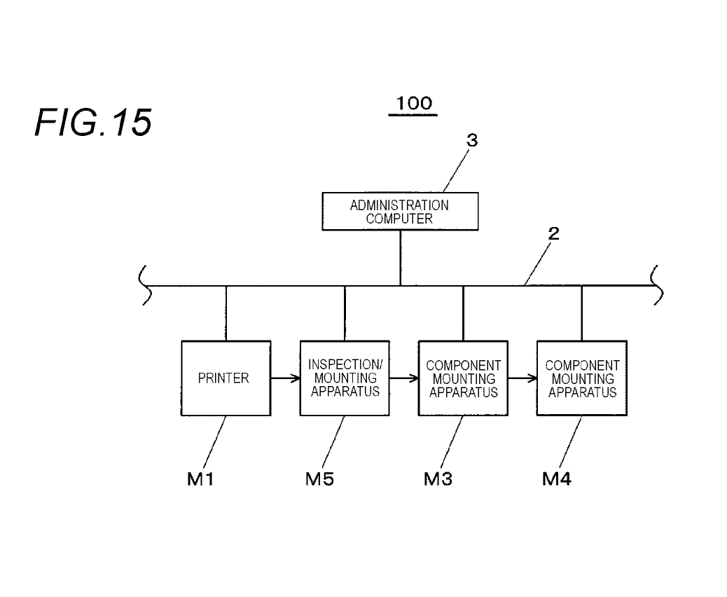

Next, the second example of the component mounting line according to the present embodiment will be described with reference to FIGS. 15 to 17. In FIG. 15, a component mounting line 100 is different from the component mounting line 1 described above in a point that the inspecting apparatus M2 positioned between the printer M1 and the component mounting apparatus M3 is replaced with an inspection/mounting apparatus M5. Since a printer M1 and component mounting apparatuses M3 and M4 of the component mounting line 100 are the same as in the component mounting line 1, the description thereof will be omitted.

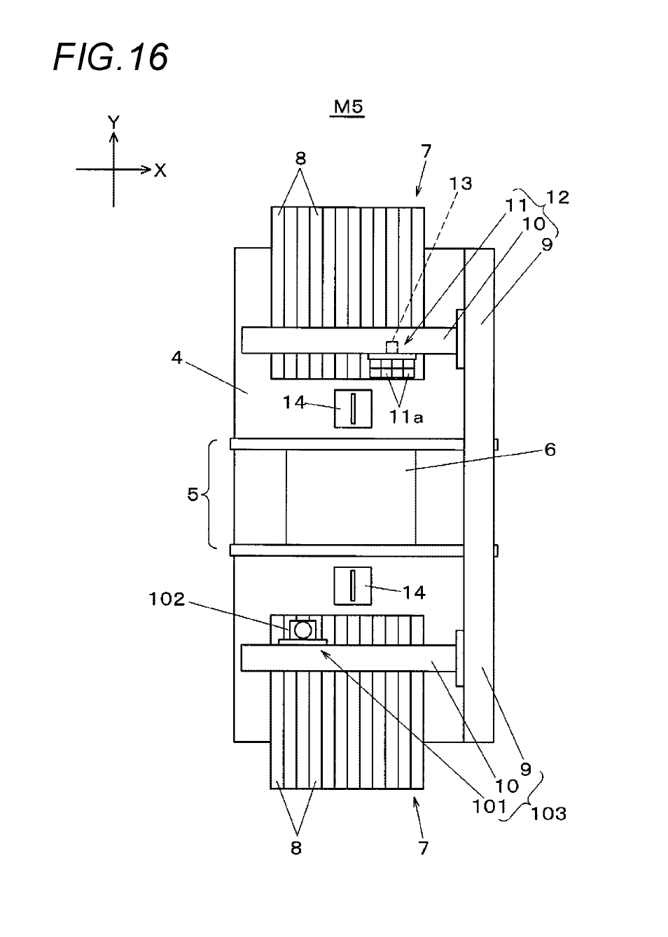

Next, the inspection/mounting apparatus M5 will be described with reference to FIG. 16. The inspection/mounting apparatus M5 has functions of inspecting the state of the printing (transferring) of cream solder by measuring measured solder amount VM (solder volume) of cream solder PS printed on each of the lands E (electrode) of a board 6, and picking up a chip solder CS and a component D from a tape feeder 8 (component supply unit) by a mounting unit 12, and moving and mounting the chip solder CS and the component D to a mounting position of the board 6 on which the cream solder PS is printed. The inspection/mounting apparatus M5 is different in a point that one of two mounting units 12 included in the component mounting apparatuses M3 and M4 (at the lower side of a paper surface in FIG. 16) is replaced with an inspecting unit. The other parts are the same with the component mounting apparatuses M3 and M4, therefore the description thereof is omitted.

In FIG. 16, in one X-axis moving table 10, an inspecting head 101 is slidably mounted in the X direction. A head traveling mechanism moves the inspecting heads 101 in a horizontal surface. The inspecting head 101 includes a three-dimensional sensor 102 including a laser light scanning type sensor or the like that moves integrally with the inspecting head 101. In the three-dimensional sensor 102, the measured solder amount VM of the cream solder PS moved to and printed on a predetermined land E of the board 6 is measured. In this manner, the head traveling mechanism and the inspecting head 101 becomes an inspecting unit 103 in which the measured solder amount VM (solder volume) of the solder printed on each of the lands E (electrode) of the board 6 is measured.

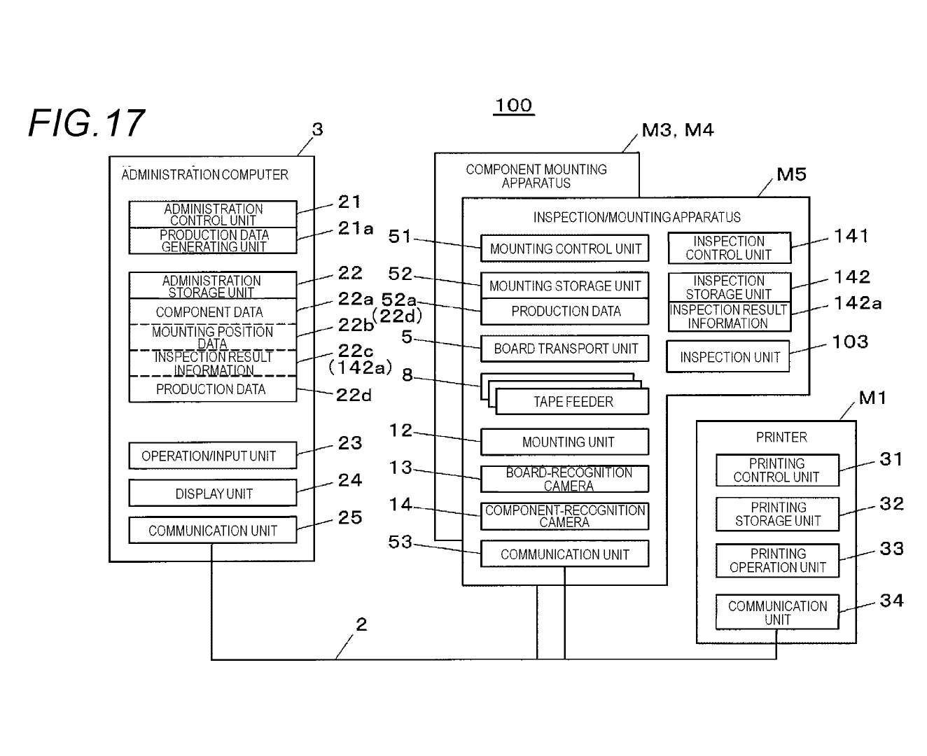

Next, the configuration of the control system of the component mounting line 100 will be described with reference to FIG. 17. The inspection/mounting apparatus M5 includes an inspection control unit 141, an inspection storage unit 142, and the inspecting unit 103 in addition to each part including the mounting unit 12, the tape feeder 8 (component supply means), the mounting control unit 51, or the like included in the component mounting apparatuses M3 and M4. The inspection control unit 141 controls the inspection unit 103 based on various types of programs or data stored in the inspection storage unit 142 and thereby, the shape of the cream solder PS printed on each of the lands E of the board 6 is measured in a three-dimensional manner by the three-dimensional sensor 102 included in the inspecting unit 103.

The inspection control unit 141 computes the measured solder amount VM at each of the lands E by arithmetically processing the measurement result. The computed measured solder amount VM is stored in the inspection storage unit 142 as inspection result information 142a. The inspection result information 142a is transmitted to the administration computer 3 through the communication unit 44 and the communication network 2, and is stored in the administration storage unit 22 as the inspection result information 22c.

The component mounting line 100 performs the component mounting operation according to the flowchart in FIG. 12 as in the component mounting line 1. In the component mounting line 100, the inspecting process (ST2), the chip solder mounting process (ST5), and the component mounting process (ST6) are performed in the inspection/mounting apparatus M5. The component mounting operation is performed, and thereby, in the component mounting line 100, the measured solder amount VM for each of the board 6 on which the cream solder PS is printed is measured, the production data 52a is generated based on the measured solder amount VM, and the chip solder CS and the component D is mounted on the board 6.

The component mounting line 100 is capable of realizing the function that has been performed in the inspecting apparatus M2 and the component mounting apparatus M3 (M4) in the component mounting line 1 at the inspection/mounting apparatus M5, and of decreasing the installation area of the line. In addition, since the inspection/mounting apparatus M5 is capable of being realized by exchanging the mounting head 11 of the component mounting apparatuses M3 (M4) with the inspecting head 101, it is possible to flexibly change the component mounting line corresponding to the produced mounting board.

In addition, in the component mounting line 1 and the component mounting line 100, as described above, an example is described, in which the production data 22d is generated in the administration computer 3, and the production data 22d is transmitted to the component mounting apparatuses M3 and M4 and the inspection/mounting apparatus M5; however, the generation and the storing method of the production data 52a are not limited to the example described above. That is, the production data 52a may be generated by the mounting control units 51 of the component mounting apparatuses M3 and M4 or the inspection/mounting apparatus M5. In addition, the various types of data which is referred to when the production data 52a is generated are stored in the administration storage unit 22 of the administration computer 3; however, the various types of data may be stored in the mounting storage units 52 of the component mounting apparatuses M3 and M4 or the inspection/mounting apparatus M5.

In addition, as above, an example is described, in which the chip solder CS and the component D are supplied from different tape feeders 8 which are provided in the same component mounting apparatus M3 (M4) or the inspection/mounting apparatus M5 and mounted on the board 6; however, the chip solder CS and the component D may be mounted on the board 6 by different component mounting apparatuses M3 and M4 or the inspection/mounting apparatus M5. For example, the chip solder CS may be supplied from the tape feeder 8 provided in the component mounting apparatus M3 and may be mounted on the board 6, and the component D may be supplied from the tape feeder 8 provided in the component mounting apparatus M4 after the board 6 is transported to the component mounting apparatus M4, and may be mounted on the board 6.

The component mounting line, the component mounting method and the component mounting apparatus according to the embodiment of the present invention may have an effect of being capable of mounting appropriately sized chip solder on a board, and is used in a component mounting field where a component is mounted on a board.

What is claimed is:

1. A component mounting line comprising:
an inspecting apparatus; and
a component mounting apparatus,
wherein the inspecting apparatus measures a solder volume of a printed solder on each electrode of a board, and
wherein the component mounting apparatus includes
a mounting unit that mounts an electronic component on the board,
at least one component supply unit that supplies a chip solder, and
a control unit that controls the mounting unit to mount the chip solder supplied from the component supply unit based on production data in which a size of the chip solder is instructed corresponding to the solder volume measured for each of component terminals corresponding to each electrode of the board.

2. The component mounting line according to claim 1,
wherein the instructed size of the chip solder is determined based on an ideal solder amount required for solder bonding of the component terminal to the electrode of the board.

3. The component mounting line according to claim 1,
wherein the instructed size of the chip solder is determined based on a size of an opening and a mask thickness of a mask used when solder is printed on the board.

4. The component mounting line according to claim 1,
wherein a plurality of component supply units are provided to supply pieces of chip solder having different sizes.

5. The component mounting line according to claim 1, further comprising:
another component supply unit that supplies the electronic component.

6. A component mounting method comprising:
measuring a solder volume of solder printed on each electrode of a board;
mounting chip solder supplied based on production data in which a size of the chip solder is instructed corresponding to the measured solder volume for each of component terminals corresponding to each electrode of the board; and
mounting an electronic component on the board.

7. The component mounting method according to claim 6,
wherein the instructed size of the chip solder is determined based on an ideal solder amount required for solder bonding of the component terminal to the electrode of the board.

8. The component mounting method according to claim 6,
wherein the instructed size of the chip solder is determined based on a size of an opening and a mask thickness of a mask used when solder is printed on the board.

9. The component mounting method according to claim 6,
wherein said mounting of the chip solder includes supplying pieces of chip solder having different sizes from a plurality of component supply units.

10. The component mounting method according to claim 6,
wherein the electronic component is supplied from another component supply unit which is different from the component supply that supplies the chip solder.

11. A component mounting apparatus comprising:
an inspecting unit that measures a solder volume of solder printed on each electrode of a board;
a mounting unit that mounts an electronic component on the board;
at least one component supply unit that supplies chip solder; and
a control unit that controls the mounting unit to mount the chip solder supplied from the component supply unit based on production data in which a size of the chip solder is instructed corresponding to the solder volume measured for each of component terminals corresponding to each electrode of the board.

12. The component mounting apparatus according to claim 11,
wherein the instructed size of the chip solder is determined based on an ideal solder amount required for solder bonding of the component terminal to the electrode of the board.

13. The component mounting apparatus according to claim 11,
wherein the instructed size of the chip solder is determined based on a size of an opening and a mask thickness of a mask used when solder is printed on the board.
